(19) United States
(12) Patent Application Publication
(10) Pub. No.: US 2021/0020533 A1
(43) Pub. Date: Jan. 21, 2021

(54) SEMICONDUCTOR DEVICE PACKAGE AND METHOD FOR MANUFACTURING THE SAME

(71) Applicant: Advanced Semiconductor Engineering, Inc., Kaohsiung (TW)

(72) Inventor: Wen-Long LU, Kaohsiung (TW)

(73) Assignee: Advanced Semiconductor Engineering, Inc., Kaohsiung (TW)

(21) Appl. No.: 16/516,122

(22) Filed: Jul. 18, 2019

(51) Int. Cl. H01L 23/31; H01L 21/56; H01L 21/683; H01L 21/48; H01L 23/00; H01L 23/498

(52) U.S. Cl. CPC H01L 23/3135; H01L 2924/35121; H01L 21/568; H01L 21/6835; H01L 21/4857; H01L 21/561; H01L 21/4853; H01L 24/97; H01L 23/49838; H01L 23/49816; H01L 24/16; H01L 24/81; H01L 24/32; H01L 24/83; H01L 24/73; H01L 24/92; H01L 2224/16227; H01L 2224/32225; H01L 2224/73204; H01L 2224/81005; H01L 2224/83005; H01L 2224/95001; H01L 2924/3511; H01L 23/3128

(57) ABSTRACT

A semiconductor device package includes an electronic component, an encapsulation layer encapsulating the electronic component, and a passivation layer stacking with the encapsulation layer. The passivation layer has a first surface facing the encapsulation layer, a second surface opposite to the first surface, and a first sidewall connecting the first surface and the second surface. The first sidewall inclines with respect to the second surface, and a first projection width of the encapsulation layer is greater than a second projection width of the passivation layer.

### BACKGROUND

### 1. Technical Field

The present disclosure relates to a semiconductor device package and a method for manufacturing the same, and to a semiconductor device package including a passivation layer and an encapsulation layer stacked with the passivation layer and laterally protruding out from the passivation layer and a method for manufacturing the same.

### 2. Description of the Related Art

Driven by miniaturization of electronic product, thickness and dimension of semiconductor package have to be decreased. However, warpage and delamination are prominent issues as a result of the miniaturization. Root cause of warpage and delamination can be attributed to external stress exerted by diamond blade cutting or thermal stress caused by elevated temperature treatment such as thermal curing.

### SUMMARY

In some embodiments, a semiconductor device package includes an electronic component, an encapsulation layer encapsulating the electronic component, and a passivation layer stacking with the encapsulation layer. The passivation layer has a first surface facing the encapsulation layer, a second surface opposite to the first surface, and a first sidewall connecting the first surface and the second surface. The first sidewall inclines with respect to the second surface, and a first projection width of the encapsulation layer is greater than a second projection width of the passivation layer.

In some embodiments, a semiconductor device package includes a passivation layer having a first sidewall, an electronic component disposed on the passivation layer, and an encapsulation layer stacked on the passivation layer and encapsulating the electronic component. The encapsulation layer has a second sidewall, and a surface roughness of the second sidewall of the encapsulation layer is different from a surface roughness of the first sidewall of the passivation layer.

In some embodiments, a method for manufacturing a semiconductor device package includes following steps. A passivation layer is formed on a carrier. An electronic component is formed on the passivation layer. An encapsulation layer is formed on the passivation layer to encapsulate the electronic components. A first opening is formed in the passivation layer by performing a first sandblasting operation. A second opening is formed in the encapsulation layer, the second opening being in connection with the first opening.

### BRIEF DESCRIPTION OF THE DRAWINGS

Aspects of some embodiments of the present disclosure are readily understood from the following detailed description when read with the accompanying figures. Various structures may not be drawn to scale, and the dimensions of the various structures may be arbitrarily increased or reduced for clarity of discussion.

FIG. 1 is a cross-sectional view of a semiconductor device package in accordance with some embodiments of the present disclosure.

FIG. 1A is an enlarged view of region “A” of a semiconductor device package in FIG. 1.

FIG. 1B is a top view of a semiconductor device package of FIG. 1.

FIG. 2 is a cross-sectional view of a semiconductor device package in accordance with some embodiments of the present disclosure.

FIG. 2A is an enlarged view of region “A” of a semiconductor device package in FIG. 2.

FIG. 3 is a cross-sectional view of a semiconductor device package in accordance with some embodiments of the present disclosure.

FIG. 4 is a cross-sectional view of a semiconductor device package in accordance with some embodiments of the present disclosure.

FIG. 5 is a cross-sectional view of a semiconductor device package in accordance with some embodiments of the present disclosure.

FIG. 6 is cross-sectional view of a semiconductor device package in accordance with some embodiments of the present disclosure.

FIG. 7A, FIG. 7B, FIG. 7C, FIG. 7D, FIG. 7E, FIG. 7F, FIG. 7G, FIG. 7H, FIG. 7I, FIG. 7J, FIG. 7K, FIG. 7L and FIG. 7M illustrate operations of manufacturing a semiconductor device package in accordance with some embodiments of the present disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In some embodiments, the present disclosure provides a semiconductor device package and a method for manufacturing the same. The semiconductor device package includes an electronic component, an encapsulation layer and a passivation layer stacking with the encapsulation layer. The sidewall of the passivation layer may be formed by sandblasting and is inclining with respect to the surface of the passivation layer. Compared to roller blade cutting, sandblasting applies a unidirectional pulling force on the passivation layer, and thus can alleviate delamination and warpage issue due to mechanical stress. Sandblasting also generates less friction, and thus can reduce heat accumulation. Accordingly, delamination and warpage issue due to thermal stress can be alleviated. The sidewall of the encapsulation may also be formed by sandblasting, and thus possesses similar advantages.

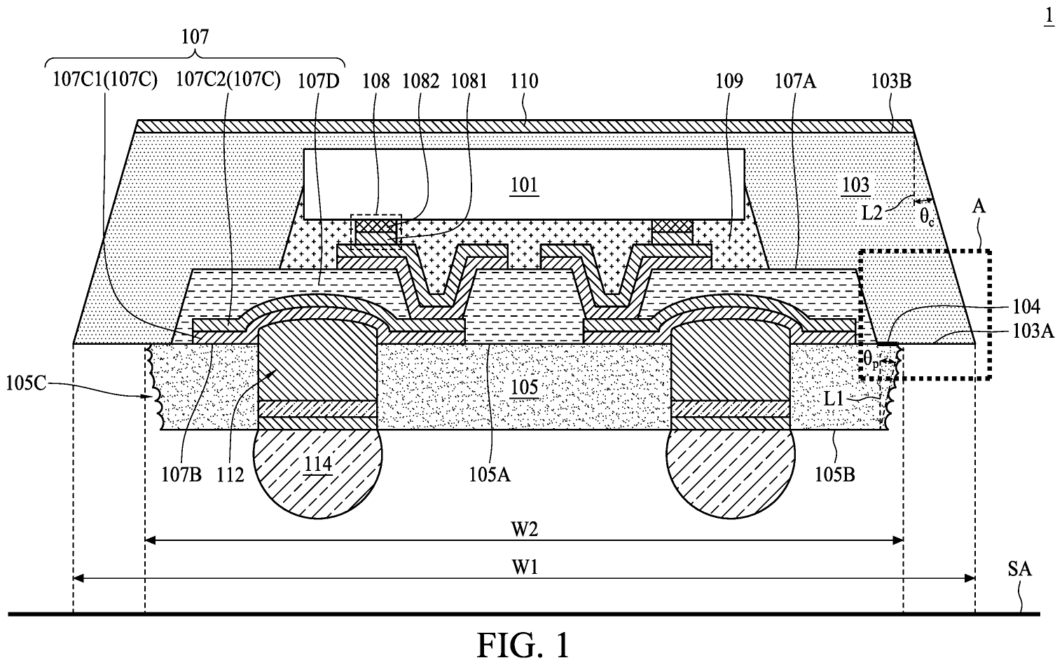

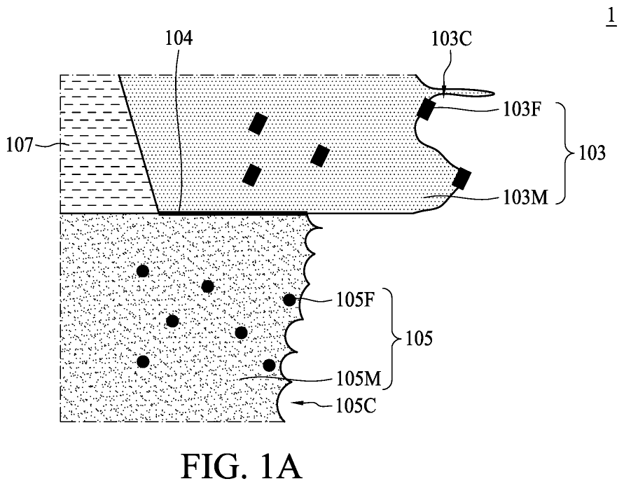

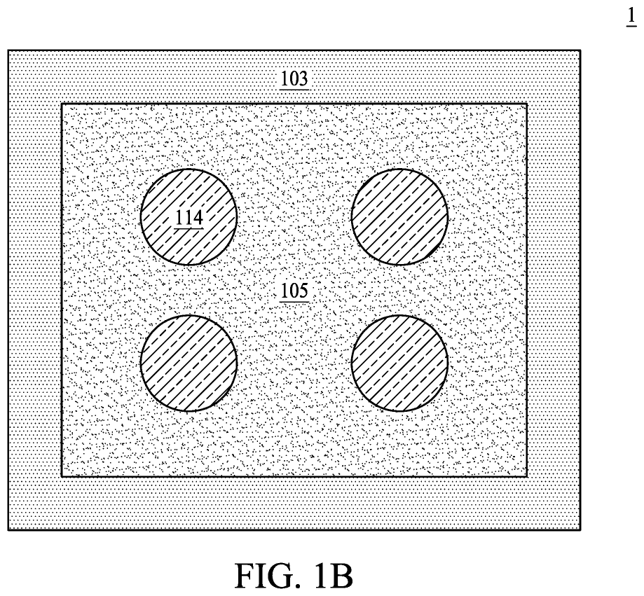

FIG. 1 is a cross-sectional view of a semiconductor device package 1 in accordance with some embodiments of the present disclosure, FIG. 1A is an enlarged view of region “A” of a semiconductor device package 1 in FIG. 1, and FIG. 1B is a top view of a semiconductor device package 1 of FIG. 1. As shown in FIG. 1, FIG. 1A and FIG. 1B, the semiconductor device package 1 includes at least one electronic component 101, an encapsulation layer 103 and a passivation layer 105. The electronic component 101 may include an active electronic component such as semiconductor die, integrated circuit or the like, a passive electronic component such as a capacitor, a resistor or the like, or a combination thereof. The encapsulation layer 103 encapsulates the electronic component 101. In some embodiments, the encapsulation layer 103 may encapsulate sidewalls of the electronic component 101. The encapsulation layer 103 may further encapsulate an active surface and/or a passive surface of the electronic component 101. The passivation layer 105 stacks with the encapsulation layer 103. The passivation layer 105 and the encapsulation layer 103 may be in contact at an interface 104.

In some embodiments, the semiconductor device package 1 may be rectangular in shape as shown in FIG. 1B. In some other embodiments, the shape of the semiconductor device package 1 may be circular, polygonal such as triangular or other regular or irregular shapes.

The passivation layer 105 has a first surface 105A facing the encapsulation layer 103, a second surface 105B opposite to the first surface 105A, and a first sidewall 105C connecting the first surface 105A and the second surface 105B. In some embodiments, the first surface 105A and the second surface 105B are substantially in parallel. The second surface 105B is smaller than the first surface 105A, and thus the first sidewall 105C is inclining with respect to the second surface 105B, forming a first inclination angle θₚ. The first inclination angle θₚ of the first sidewall 105C of the passivation layer 105 with respect to a first imaginary line L1 normal to the second surface 105B is greater than 0 degree. By way of example, the first inclination angle θₚ of the first sidewall 105C of the passivation layer 105 with respect to the first imaginary line L1 is, but not limited to be, ranging from about 20 degrees to about 70 degrees.

In some embodiments, the thickness of the encapsulation layer 103 is larger than the thickness of the passivation layer 105. The encapsulation layer 103 has a third surface 103A facing the passivation layer 105, a fourth surface 103B opposite to the third surface 103A, and a second sidewall 103C connecting the third surface 103A and the fourth surface 103B. The third surface 103A and the fourth surface 103B may be substantially in parallel. The encapsulation layer 103 has a first projection width W1 projected on an imaginary plane SA along the first imaginary line L1, and the passivation layer 105 has a second projection W2 projected on the imaginary plane SA along the first imaginary line L1. The first projection width W1 may be the maximum width of the encapsulation layer 103, and the second projection width W2 may be the maximum width of the passivation layer 105. For example, the first projection width W1 may be the width of the third surface 103A of the encapsulation layer 103, and the second projection width W2 may be the width of the first surface 105A of the passivation. The first projection width W1 of the encapsulation layer 103 is greater than the second projection width W2 of the passivation layer 105, such that the encapsulation layer 103 hangs over the passivation layer 105. In some embodiments, the difference between the first projection width W1 and the second projection width W2 is greater than 40 micrometers. In some embodiments, the fourth surface 103B is smaller than the third surface 103A, and thus the second sidewall 103C is inclining with respect to the fourth surface 103B, forming a second inclination angle θ_{c}. The second inclination angle θ_{c} of the second sidewall 103C of the encapsulation layer 103 with respect to a second imaginary line L2 normal to the fourth surface 103B is greater than 0 degree. By way of example, the second inclination angle θ_{c} of the second sidewall 103C of the encapsulation layer 103 with respect to the second imaginary line L2 is, but not limited to, ranging from about 20 degrees to about 70 degrees. In some embodiments, the second sidewall 103C and the third surface 103A of the encapsulation layer 103 may include an acute included angle.

The semiconductor device package 1 may further include a circuit layer 107 disposed between the passivation layer 105 and the encapsulation layer 103. The circuit layer 107 may be disposed under the electronic component 101 and electrically connected to the electronic component 101. The dimension such as width of the circuit layer 107 is smaller than that of the passivation layer 105 and that of the encapsulation layer 103 such that the passivation layer 105 and the encapsulation layer 103 may be in contact at an interface 104. In some embodiments, the circuit layer 107 may include one or more dielectric layers 107D, and one or more conductive layers 107C stacked with the dielectric layer 107D. The number of the dielectric layer 107D and the conductive layer 107C can be modified based on electrical connection specification. Each of the conductive layers 107C may be a multi-layered conductive layer including a seed layer 107C1 and a metal layer 107C2, for example. In some embodiments, a conductive layer 107B may be disposed on a fifth surface 107A of the dielectric layer 107D facing the encapsulation layer 103, and another conducive layer 107B may be disposed on a sixth surface 107B of the dielectric layer 107 facing the passivation layer 105. The conductive layer 107 disposed on one of the fifth surface 107A and the sixth surface 107B may penetrate through the dielectric layer 107D and connects the conductive layer 107 disposed on the other one of the fifth surface 107A and the sixth surface 107B. In some embodiments, the electronic component 101 may be flip chip bonded to the circuit layer 107 through interconnection structures 108. The interconnection structure 108 may include a bump 1081 such as a micro bump and a solder 1082. In some embodiments, a bonding pad such as a UBM pad may be interposed between the bump 1081 and the solder 1082. In some embodiments, the interconnection structure 108 may include a pair of bumps such as copper bumps directly bonded to each other. In some other embodiments, the electronic component 101 may be electrically connected to the circuit layer 107 in other manners such as wire bonding.

In some embodiments, the semiconductor device package 1 may further include an underfill 109 disposed between the electronic component 101 and the circuit layer 107. In some embodiments, the underfill 109 may be omitted, and the encapsulation layer 103 may be further extended into the region between the electronic component 101 and the circuit layer 107, and configured as molding underfill (MUF). In some embodiments, a stress buffering layer 110 may be optionally disposed on the fourth surface 103B of the encapsulation layer 103 to adjust stress.

The semiconductor device package 1 further includes a conductive structure 112 penetrating through the passivation layer 105 and electrically connected to the circuit layer 107, and an electrical conductor 114 disposed on the second surface of the passivation layer and electrically connected to the conductive structure 112. In some embodiments, the conductive structure 112 may include conductive pillars or the like. The conductive structure 112 may include a multi-layered conductive structure 112 including a stack of gold/nickel/copper, for example. The electrical conductor 114 may include a solder ball, a solder bump such as C4 bump, BGA (ball grid array) bump, LGA (land grid array) bump, solder paste or the like. In some embodiments, the electrical conductor 114 can be implanted on the conductive structure 112 or formed by electroplating.

The characteristics of the passivation layer 105 and the encapsulation layer 103 are different. For example, the passivation layer 105 is softer than the encapsulation layer 103. The materials, additives and/or fillers of the passivation layer 105 and the encapsulation layer 103 may be different. As shown in FIG. 1A, the passivation layer 105 may include a base material 105M. The base material 105M may include organic material such as epoxy, polyimide, solder mask material such as acrylic solder mask material (ink) or the like, inorganic material such as silicon oxide, silicon nitride, silicon oxynitride, tantalum oxide, glass, silicon, ceramic or the like, or other suitable insulating or dielectric material. The base material 105M may be in forms of liquid or film, and can be formed by deposition or other suitable process. In some embodiments, the base material 105M may be a filler-free material. In some embodiments, the passivation layer 105 may further include first fillers 105M dispersed in the base material 105M. The first fillers 105F may include pellet fillers such as silicon oxide or the like. The encapsulation layer 103 may include a base material 103M. The base material 103M may include molding compound such as resin or the like. In some embodiments, the encapsulation layer 103 may further include second fillers 103F dispersed in the base material 103M. The second fillers 103F may include filiform fillers such as fiber fillers, pellet fillers such as silicon oxide or the like. In some embodiments, the dimension of the second filler 103F is larger than the dimension of the first filler 105F. The dimension of the second filler 103 may be ranging from about 5 micrometers to about 15 micrometers. In some embodiments, at least a portion of the second fillers 103F may be cut during fabrication and exposed from the second sidewall 103C of the encapsulation layer 103. In some embodiments, at least a portion of the first fillers 105F may be cut during fabrication and exposed from the first sidewall 105C of the passivation layer 105.

In some embodiments, the first sidewall 105C of the passivation layer 105 may be formed by sandblasting such as pneumatic sandblasting. In contrast to roller blade cutting which generates both pulling force and pushing force resulting in warpage and delamination problem, sandblasting not only is less expensive, but also generates a unidirectional force on the passivation layer 105. The cutting effect or bombing effect of sandblasting can be stopped at the surface of ductile material such as the conductive layer 107C (e.g., copper layer), and thus the delamination between the passivation layer 105 and the encapsulation 103, the passivation layer 105 and the circuit layer 107 or the encapsulation layer 103 and the circuit layer 107 can be alleviated. In some embodiments, the second sidewall 103C of the encapsulation layer 103 may be formed by sandblasting such as pneumatic sandblasting. The sandblasting powers used to cutting the encapsulation layer 103 may be different from that used to cutting the passivation layer 105. For example, the sandblasting powers used to cutting the encapsulation layer 103 may be smaller than that used to cutting the passivation layer 105.

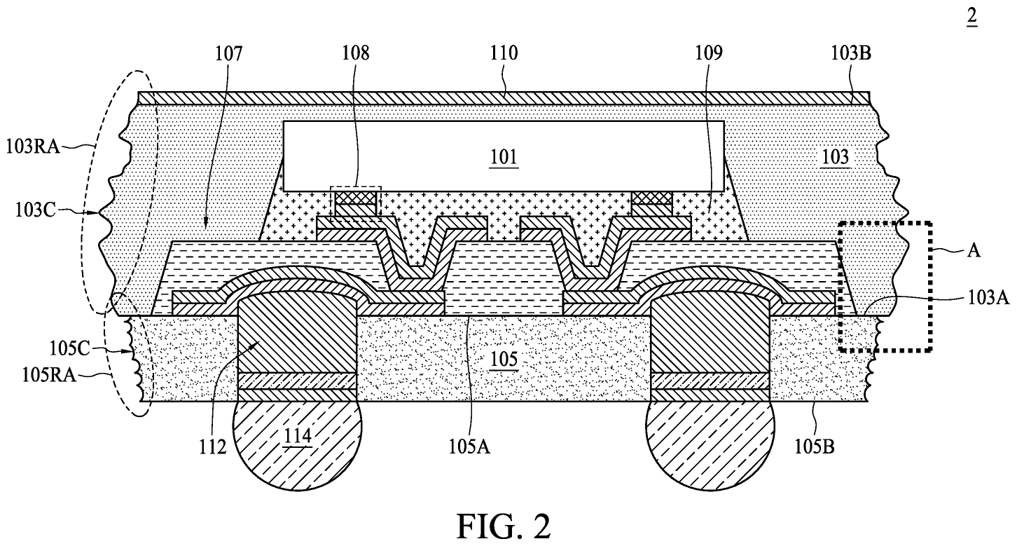

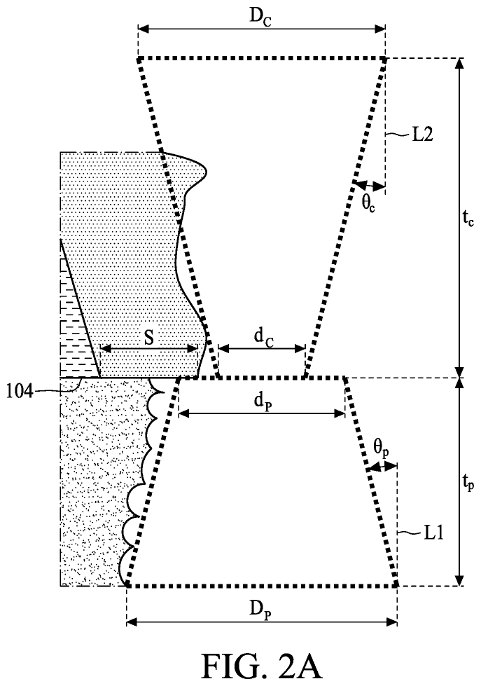

FIG. 2 is a cross-sectional view of a semiconductor device package 2 in accordance with some embodiments of the present disclosure, and FIG. 2A is an enlarged view of region “A” of a semiconductor device package 2 in FIG. 2. In contrast to the semiconductor device package 1 in FIG. 1, at least one of the second sidewall 103C of the encapsulation layer 103 and the first sidewall 105C of the passivation layer 105 may include a rough surface. By way of example, the second sidewall 103C may have a surface roughness 103RA, and the first sidewall 105C of the passivation layer 105 may have a surface roughness 105RA. In some embodiments, the surface roughness 103RA of the encapsulation layer 103 is larger than the surface roughness 105RA of the first sidewall 105C of the passivation layer 105. The surface roughness 103RA and the surface roughness 105RA may be measured by an arithmetical mean roughness (Ra). By way of example, the arithmetical mean roughness (Ra) of the first sidewall 105C of the passivation layer 105 may be less than about 8 micrometers such as in a range between about 0.5 micrometers and about 4 micrometers. The arithmetical mean roughness (Ra) of the second sidewall 103C of the encapsulation layer 103 may be equal to or greater than about 8 micrometers such as in a range between about 8 micrometers and about 15 micrometers.

In some embodiments, the maximum dimension of a scribe-street of the encapsulation layer Dc can be derived from or determined by the following equations.

dc=Dc−2*tc*tan(θ_{c}) (1)

dp=Dp−2*tp*tan(θₚ) (2)
where,
tc is the thickness of the encapsulation layer;
tp is the thickness of the passivation layer;
Dp is the maximum dimension of a scribe-street of the passivation layer;
θₚ is the first inclination angle; and
θ_{c} is the second inclination angle.

Given the maximum dimension (bottom width) of the scribe-street of the passivation layer 105 should be larger than the maximum dimension (upper width) of the scribe-street of the encapsulation layer Dc, a difference D between the second sidewall 103C and the first sidewall 105C can be expressed by the following equation.

D=0.5(dp−dc)=0.5[Dp−Dc−2(tp*tan(θₚ)−tc*tan(θc)) (3)

From the geometry relationship as shown in FIG. 2A, D is a positive value (D>0), and can be derived from the following equation.

Dc<Dp−2*tp*tan(θₚ)+2*tc*tan(θ_{c}) (4)

From equation (4), it can be seen that the maximum dimension Dp of the scribe-street of the passivation layer 105 may be one of the design rule to determine the scribe-street of the encapsulation layer Dc.

Another design rule as shown in equation (5) can also be considered when determining the scribe-street of the encapsulation layer Dc.

Dc=B−2S+2*tc*tan(θc) (5)
where,
B is a distance between the edges of the dielectric layers of two adjacent units prior to singulation; and
S is the minimum gap between the edge of the dielectric layer and the second sidewall of the encapsulation layer.

Examples of ranges of the above parameters are illustrated as follows. The distance B between the edges of the dielectric layers 107D of two adjacent units prior to singulation is ranging from about 200 micrometers to about 500 micrometers. The minimum gap S between the edge of the dielectric layer 107D and the second sidewall 103C of the encapsulation layer 103 is ranging from about 5 micrometers to about 20 micrometers. The thickness tc of the encapsulation layer 103 is ranging from about 5 micrometers to about 20 micrometers. The thickness tp of the passivation layer 105 is ranging from about 5 micrometers to about 20 micrometers. The first inclination angle θₚ is ranging from ranging from about 20 degrees to about 70 degrees. The second inclination angle θ_{c} is ranging from ranging from about 20 degrees to about 70 degrees. The maximum dimension Dp of the scribe-street of the passivation layer 105 is ranging from about 100 micrometers to about 200 micrometers. The maximum dimension Dc of the scribe-street of the encapsulation layer 103 is ranging from about 80 micrometers to about 160 micrometers. The difference D between the second sidewall 103C and the first sidewall 105C is greater than 20 micrometers.

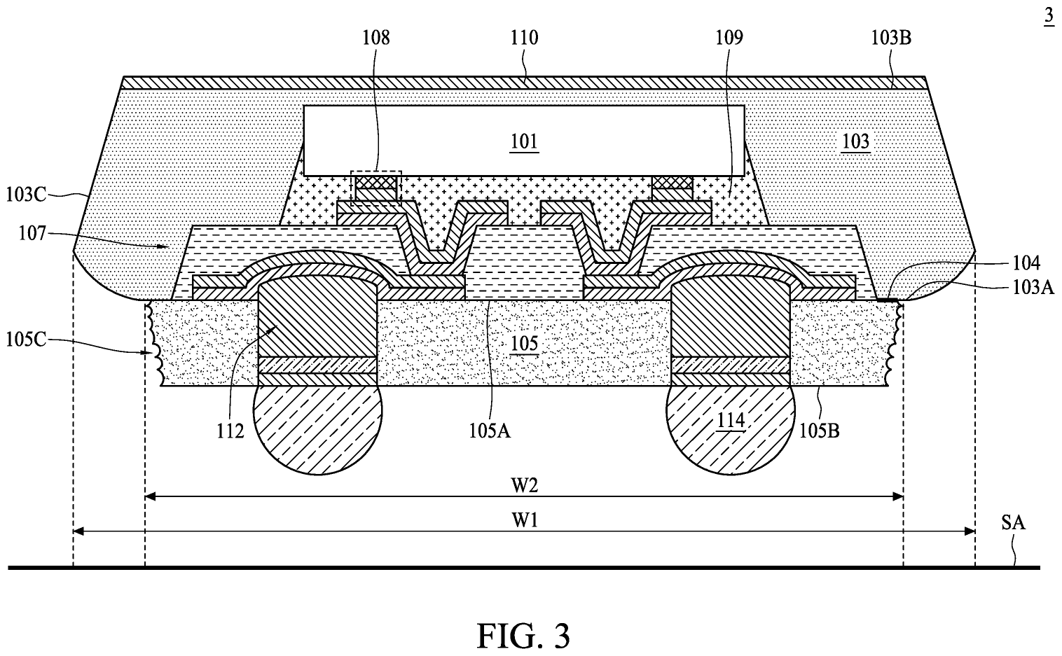

FIG. 3 is a cross-sectional view of a semiconductor device package 3 in accordance with some embodiments of the present disclosure. In contrast to the semiconductor device package 1 in FIG. 1, the first projection width W1 may be the maximum width of the encapsulation layer 103 between the third surface 103A and the fourth surface 103B. In addition, the included angle between the second sidewall 103C and the third surface 103A of the encapsulation layer 103 may be a fillet angle or a chamfer angle as shown in FIG. 3. The fillet angle or chamfer angle design may help reduce the risk of crack of the encapsulation layer 103.

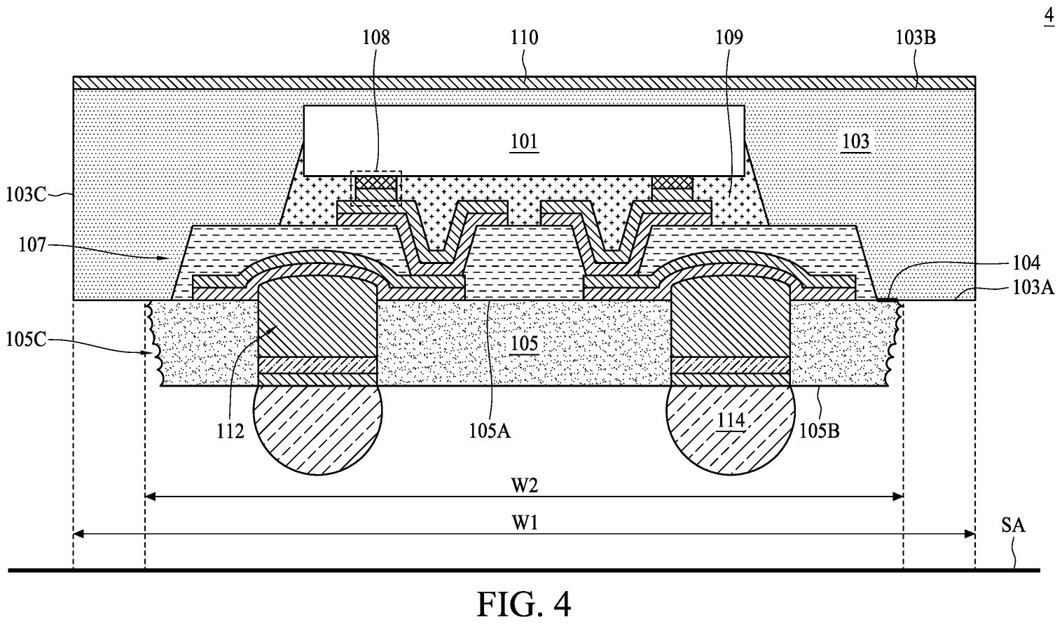

FIG. 4 is a cross-sectional view of a semiconductor device package 4 in accordance with some embodiments of the present disclosure. In contrast to the semiconductor device package 1 in FIG. 1, the second sidewall 103C of the encapsulation layer 103 is substantially perpendicular to the fourth surface 103B as shown in FIG. 4. The first surface 103A and the second surface 103B of the encapsulation layer 103 may be substantially the same. The first projection width W1 may be the width of the encapsulation layer 103 between the third surface 103A and the fourth surface 103B. The first sidewall 105C of the passivation layer 105 may be inclining with respect to the second surface 105B. In some embodiments, the surface roughness of the second sidewall 103C may be smaller than that of the first sidewall 105C. In some embodiments, the second sidewall 103C of the encapsulation layer 103 may be formed by mechanical cutting such as roller blade cutting such as diamond blading cutting, while the first sidewall 105C of the passivation layer 105 may be formed by sandblasting.

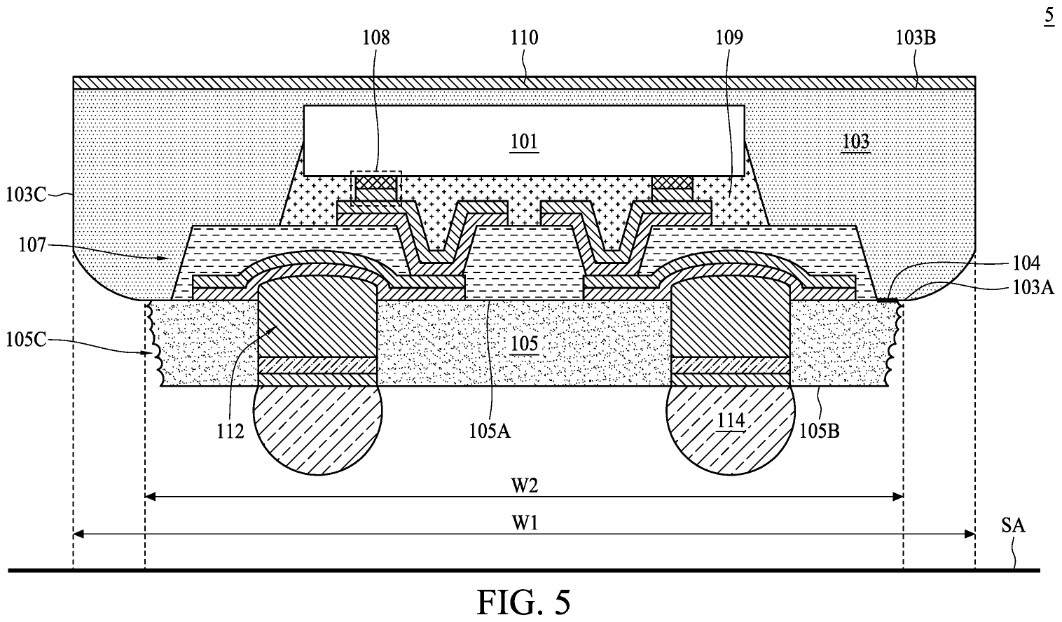

FIG. 5 is a cross-sectional view of a semiconductor device package 5 in accordance with some embodiments of the present disclosure. In contrast to the semiconductor device package 3 in FIG. 4, the first projection width W1 may be the maximum width of the encapsulation layer 103 adjacent to the fourth surface 103B than to third surface 103A. In addition, the included angle between the second sidewall 103C and the third surface 103A of the encapsulation layer 103 may be a fillet angle or a chamfer angle as shown in FIG. 5. The fillet angle or chamfer angle design may help reduce the risk of crack of the encapsulation layer 103.

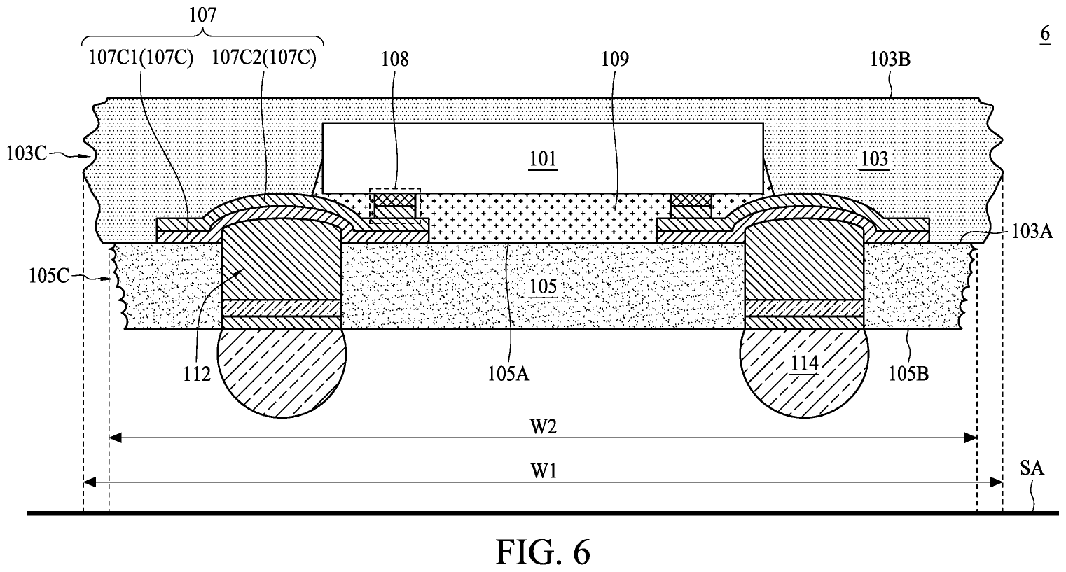

FIG. 6 is cross-sectional view of a semiconductor device package 6 in accordance with some embodiments of the present disclosure. In contrast to the semiconductor device package 1 in FIG. 1, the dielectric layer 107D of the circuit layer 107 may be omitted, and the conductive layer 107 can be formed on the passivation layer 105.

The semiconductor device packages and manufacturing methods of the present disclosure are not limited to the above-described embodiments, and may be implemented according to other embodiments. To streamline the description and for the convenience of comparison between various embodiments of the present disclosure, similar components the following embodiments are marked with same numerals, and may not be redundantly described.

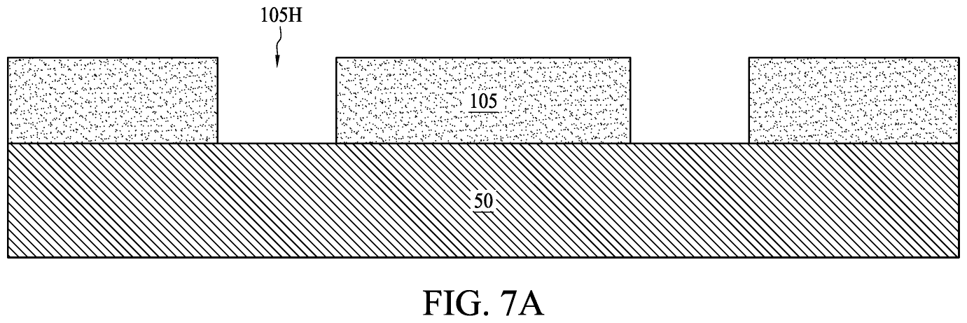

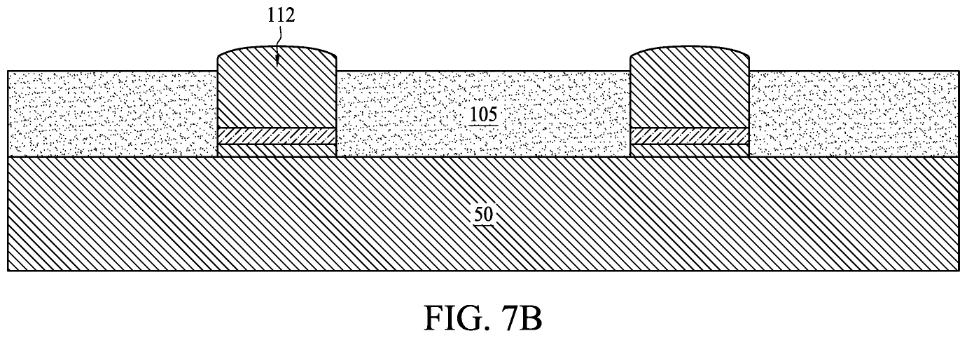

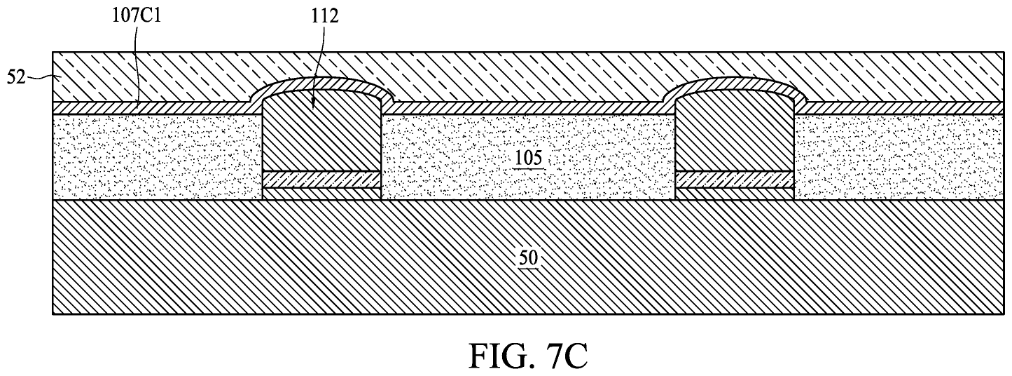

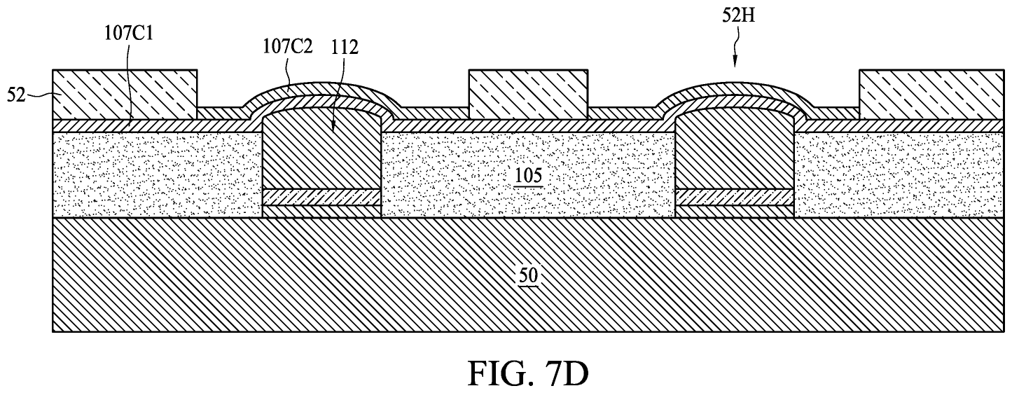

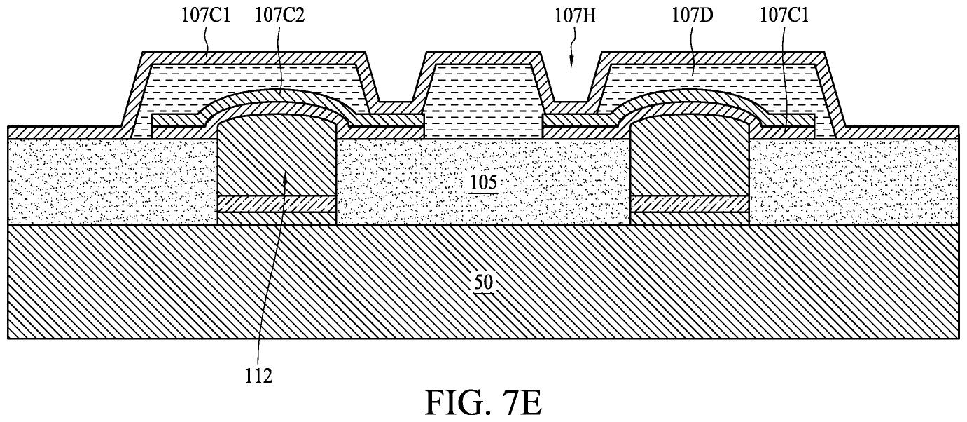

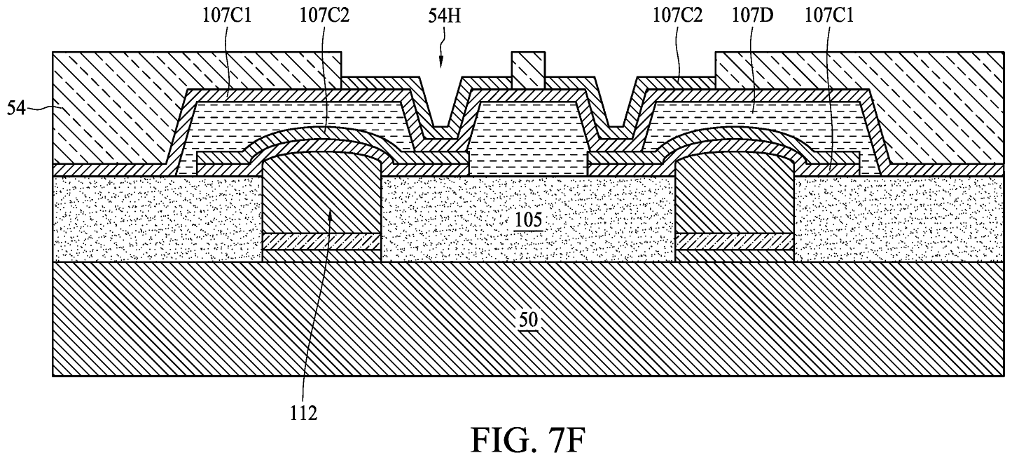

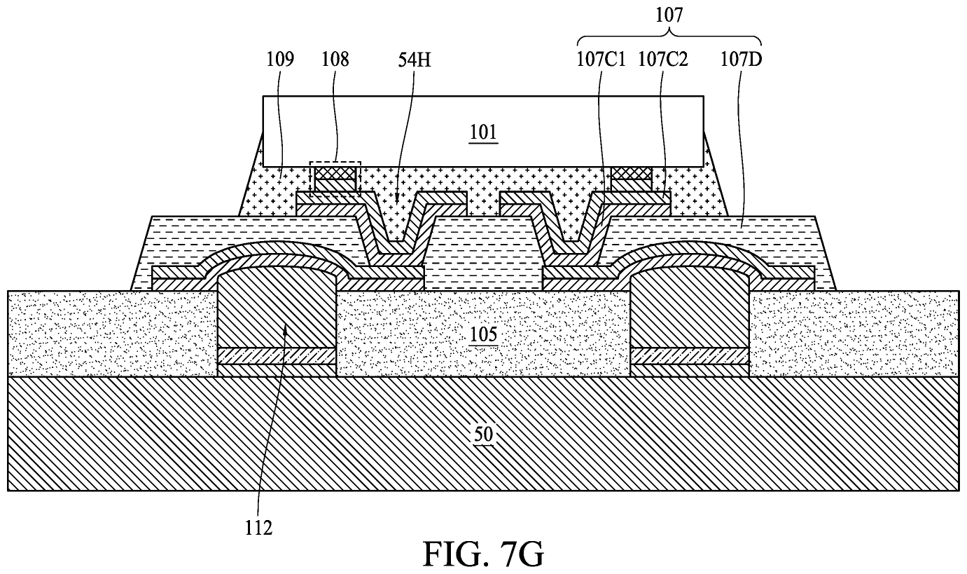

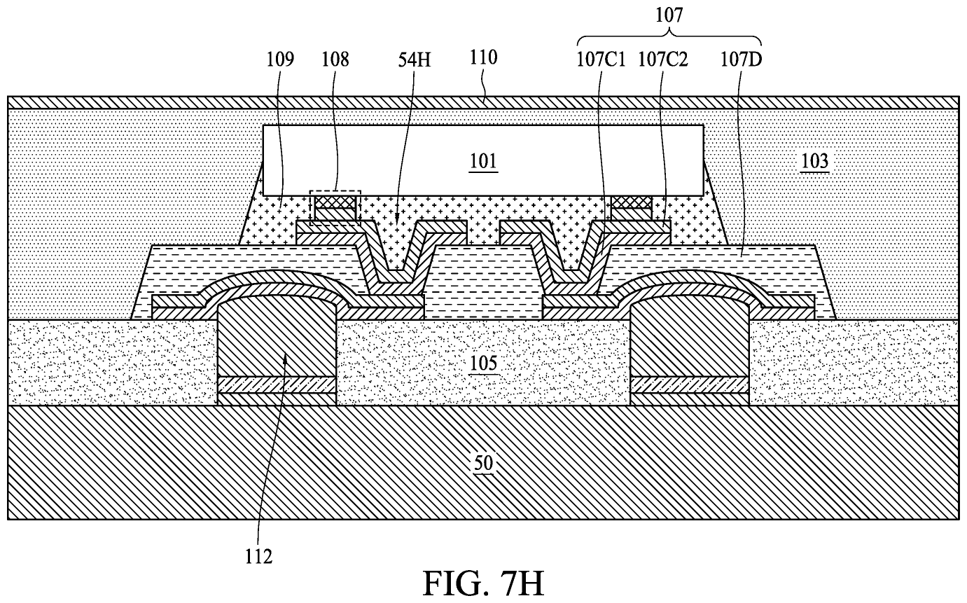

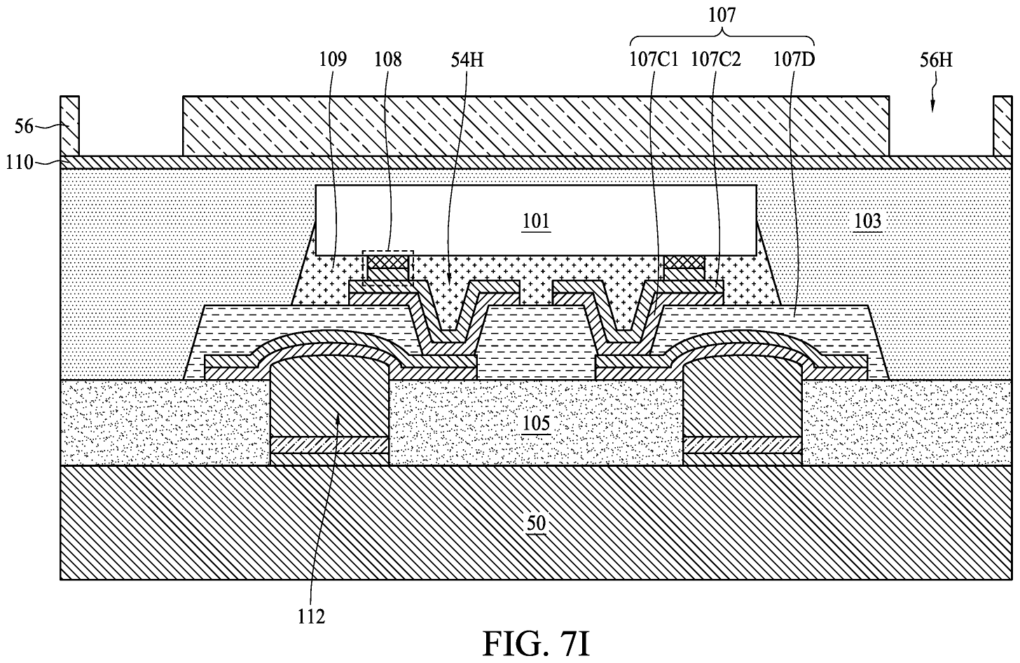

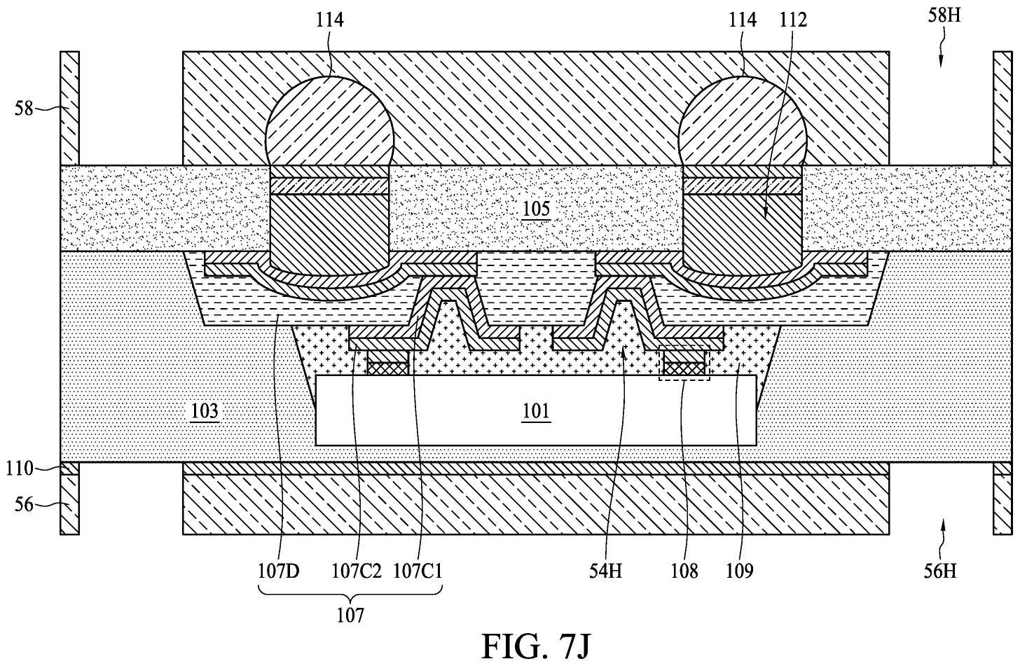

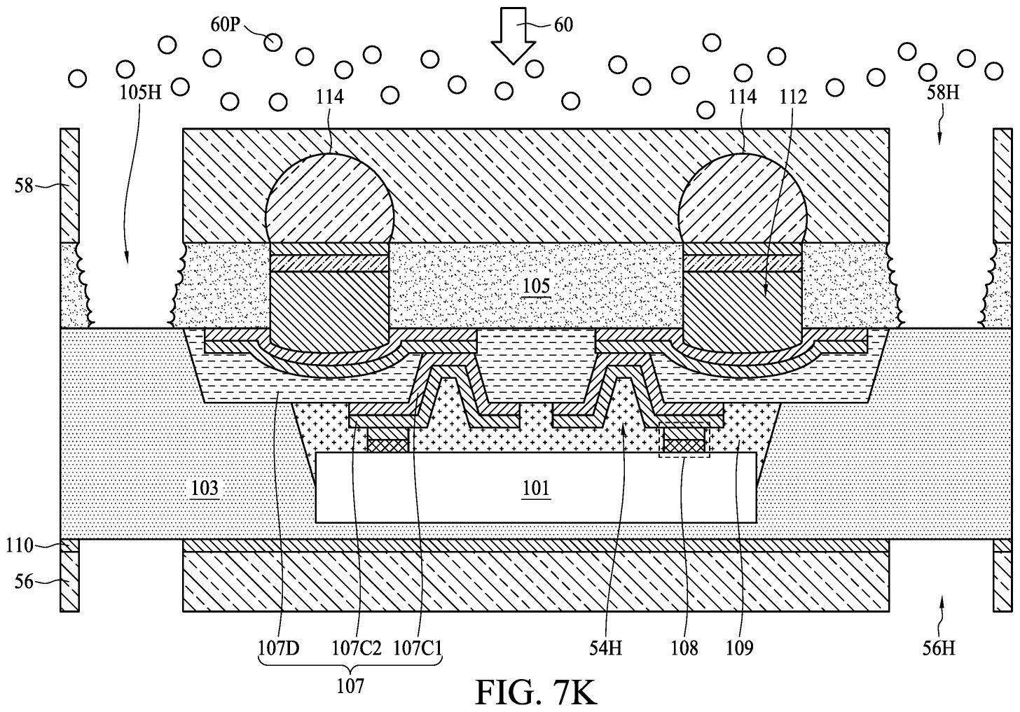

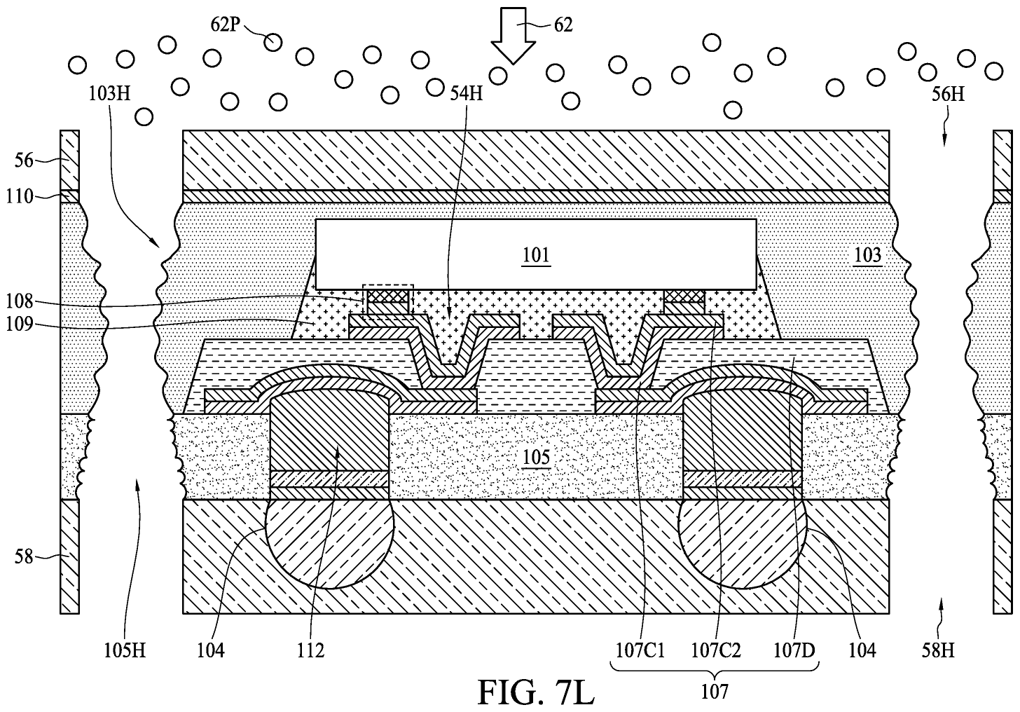

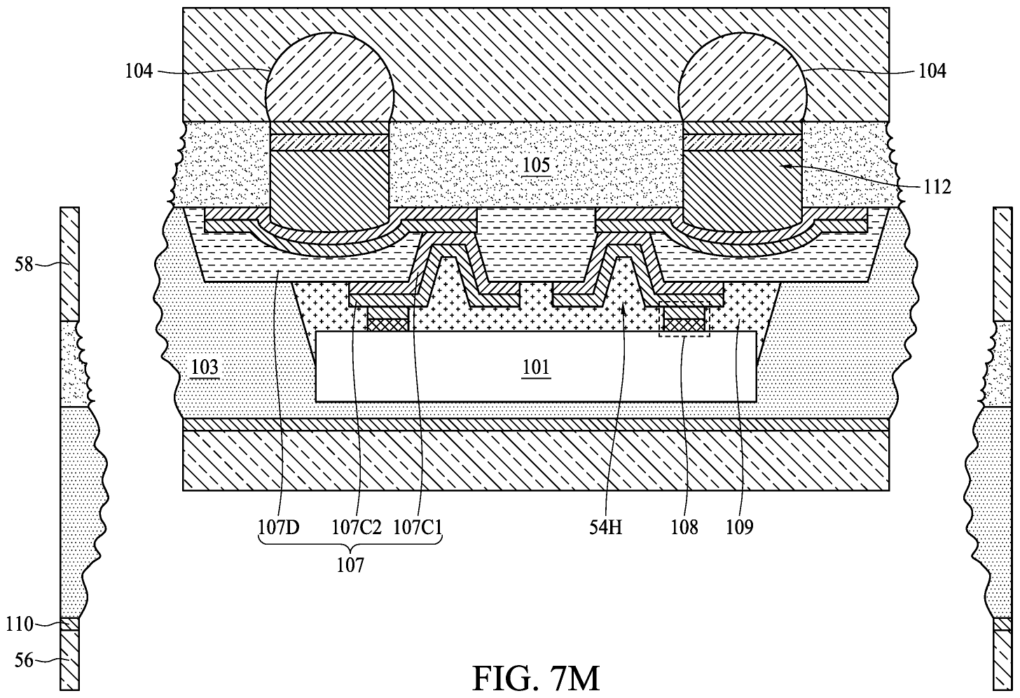

FIG. 7A, FIG. 7B, FIG. 7C, FIG. 7D, FIG. 7E, FIG. 7F, FIG. 7G, FIG. 7H, FIG. 7I, FIG. 7J, FIG. 7K, FIG. 7L and FIG. 7M illustrate operations of manufacturing a semiconductor device package in accordance with some embodiments of the present disclosure. As shown in FIG. 7A, a carrier 50 is received. The carrier 50 may include an inorganic carrier such as a metal carrier, a glass carrier, a silicon carrier, a ceramic carrier, or an organic carrier such as Bismaleimide Triazine Resin, Polypropylene, Ajinomoto Build-up Film (ABF) or the like. The A passivation layer 105 is formed on the carrier 50. The passivation layer 105 can be a film form passivation layer attached to the carrier 50, or a liquid form passivation dispensed on the carrier 50. In some embodiments, the material of the passivation layer 105 may include a photo-sensitive material. The passivation layer 105 is then patterned to form holes 105H. The passivation layer 105 can be, but is not limited to be, patterned by photolithography.

As shown in FIG. 7B, conductive structures 112 are formed in the holes 105H. In some embodiments, the conductive structures 112 may include a stack of conductive films such as a stack of gold/nickel/copper, and can be formed by electroplating or the like.

As shown in FIG. 7C, a seed layer (e.g., a bottom seed layer) 107C1 may be formed by e.g., physical vapor deposition (PVD) on the passivation layer 105. A masking layer 52 such as a photoresist layer is formed on the seed layer 107C1.

As shown in FIG. 7D, the masking layer 52 can be patterned by e.g., photolithography to form apertures 52H partially exposing the seed layer 107C1 over the conductive structures 112. A metal layer (e.g., a bottom metal layer) 107C2 such as copper layer can be formed by e.g., electroplating, on the exposed seed layer 107C1.

As shown in FIG. 7E, the masking layer 52 is removed. The seed layer 107C1 is then patterned. A dielectric layer 107D is formed on the passivation layer 105, the seed layer 107C1 and the metal layer 107C2. The material of the dielectric layer 107D may be the same as or different from that of the passivation layer 105. The dielectric layer 107D is patterned by e.g., photolithography to form openings 107H partially exposing the metal layer 107C2. Another seed layer (e.g., a top seed layer) 107C1 may be formed by e.g., PVD on the dielectric layer 107D and electrically connected to the exposed metal layer 107C2.

As shown in FIG. 7F, another masking layer 54 such as a photoresist layer is formed on the seed layer 107C1. The masking layer 54 can be patterned by e.g., photolithography to form apertures 54H partially exposing the seed layer 107C1 over the metal layer 107C2. Another metal layer (e.g., a top metal layer) 107C2 such as copper layer can be formed by e.g., electroplating, on the exposed seed layer 107C1. The dielectric layer 107D, the seed layer(s) 107C1 and the metal layer(s) 107C2 may collectively form a circuit layer 107.

As shown in FIG. 7G, interconnection structures 108 may be formed on the circuit layer 107. In some embodiments, the interconnection structure 108 may be formed by electroplating or the like. One or more electronic components 101 are bonded to and electrically connected to the circuit layer 107 through the interconnection structures 108 by flip chip bonding, for example. In some embodiments, an underfill 109 may be formed between the electronic component 101 and the circuit layer 107.

As shown in FIG. 7H, an encapsulation layer 103 is formed on the circuit layer 107 to encapsulate the electronic component 101. In some embodiments, a stress buffering layer 110 such as a metal layer may be optionally formed on the encapsulation layer 103.

As shown in FIG. 7I, the stress buffering layer 110 may be patterned to define a region of a scribe-street of the encapsulation layer 103. In some embodiments, the stress buffering layer 110 may be patterned by etching through apertures 56H of a masking layer 56 such as a photoresist layer which can be patterned by photolithography.

As shown in FIG. 7J, the carrier 50 and structures formed thereon may be flipped over, and the carrier 50 is removed. In some embodiments, the carrier 50 may, but is not limited to be removed by wet etching, dry etching such as plasma etching, machinery operation such as peeling or shearing, or laser releasing to expose the passivation layer 105 and the conductive structures 112. In some embodiments, the exposed surface of the conductive structure 112 may be a rough surface when the carrier 50 is removed by etching, a tearing interface when the carrier 50 is removed by machinery operation, or a pothole surface when the carrier 50 is removed by laser releasing. Electrical conductors 114 such as solder balls are formed on the conductive structures 112. Another masking layer 58 such as a photoresist layer is then formed on the passivation layer 105. The masking layer 58 can be patterned by e.g., photolithography to form apertures 58H to define a location of a scribe-street of the passivation layer 105. In some embodiments, the apertures 56H of the masking layer 56 on the encapsulation layer 103 are substantially aligning with the apertures 58H of the masking layer 58 on the passivation layer 105. The dimension of the apertures 56H and that of the apertures 58H can be selected to define the maximum dimension Dc of the scribe-street of the encapsulation layer 103 and the maximum dimension Dp of the scribe-street of the passivation layer 105 determined by the design rules described in aforementioned description.

As shown in FIG. 7K, a first sandblasting operation 60 is performed on the passivation layer 105 through the apertures 58H of the masking layer 58 to form first openings 105H. In some embodiments, the first sandblasting operation 60 includes a pneumatic sandblasting operation using first sandblasting powders 60P. The pneumatic sandblasting operation may be performed by injecting the first sandblasting powders 60P with inert gas such as nitrogen gas. In some embodiments, the pressure of the gas may be ranging from about 2 kg/cm² to about 10 kg/cm². The pneumatic sandblasting operation is a dry operation, which may not need liquid or solvent, and thus can avoid oxidization issue of metal material such as the circuit layer 107. The dimension of the first sandblasting powders 60P may be smaller than the dimension of a base material 105M (as shown in FIG. 1A) and the dimension of a first filler 105F of the passivation layer 105, such that the base material 105M and the first filler 105F are not damaged during the first sandblasting operation 60. The type of the first sandblasting powders 60P may include metal such as iron, steel, ceramic, glass, plastic such as resin, etc. The shape of the first sandblasting powders 60P may include bead shape, oval shape, rod shape or other shapes. In some embodiments, the first sidewall 105C of the passivation layer 105 may be inclining with respect to the second surface 105B after the first sandblasting operation 60 as shown in FIG. 1 or FIG. 2. In some embodiments, the first sidewall 105C of the passivation layer 105 may have a rough surface as shown in FIG. 1A and FIG. 2A after the first sandblasting operation 60. In some embodiments, at least a portion of the first filler 105F may be cut during the first sandblasting operation 60 and exposed from the first sidewall 105C of the passivation layer 105 as shown in FIG. 1A.

As shown in FIG. 7L, a second sandblasting operation 62 may be performed on the encapsulation layer 103 through the apertures 56H of the masking layer 56 to form second openings 103H. In some embodiments, the second sandblasting operation 62 includes a pneumatic sandblasting operation using second sandblasting powders 62P. The pneumatic sandblasting operation may be performed by injecting the second sandblasting powders 62P with inert gas such as nitrogen gas. In some embodiments, the pressure of the gas may be ranging from about 2 kg/cm² to about 10 kg/cm². The pneumatic sandblasting operation is a dry operation, which may not need liquid or solvent, and thus can avoid oxidization issue of metal material such as the circuit layer 107. The dimension of the second sandblasting powders 62P may be smaller than the dimension of a base material 103M (as shown in FIG. 1A) and the dimension of a second filler 103F of the encapsulation layer 103, such that the base material 103M and the second filler 103F are not damaged during the second sandblasting operation 62. The type of the first sandblasting powders 60P may include metal such as iron, steel, ceramic, glass, plastic such as resin, etc. The shape of the second sandblasting powders 62P may include bead shape, oval shape, rod shape or other shapes. In some embodiments, the second sidewall 103C of the encapsulation layer 103 may be inclining with respect to the fourth surface 103B after the second sandblasting operation 62 as shown in FIG. 1 or FIG. 2. In some embodiments, the second sidewall 103C of the encapsulation layer 103 may have a rough surface as shown in FIG. 1A and FIG. 2A after the second sandblasting operation 62. In some embodiments, at least a portion of the second filler 103F may be cut during the second sandblasting operation 62 and exposed from the second sidewall 103C of the encapsulation layer 103 as shown in FIG. 1A.

In contrast to roller blade cutting which generates both pulling force and pushing force resulting in warpage and delamination problem, the first sandblasting operation 60 generates a unidirectional pulling force on the passivation layer 105, and the second sandblasting operation 60 generates a unidirectional pulling force on the encapsulation layer 103. The cutting effect or bombing effect of sandblasting can be stopped at the surface of ductile material such as the conductive layer 107C, and thus the delamination between the passivation layer 105 and the encapsulation 103, the passivation layer 105 and the circuit layer 107 or the encapsulation layer 103 and the circuit layer 107 can be alleviated. In addition, compared to roller blade cutting and laser drilling, heat is not accumulated during sandblasting because less friction is generated. Accordingly, delamination due to thermal stress between the passivation layer 105 and the encapsulation 103, the passivation layer 105 and the circuit layer 107 or the encapsulation layer 103 and the circuit layer 107 can be alleviated.

The rigidity of the passivation layer 105 and that of the encapsulation layer 103 is different, and thus the type and dimension of the first sandblasting powders 60P is different from that of the second sandblasting powders 62P. In some embodiments, the passivation layer 105 is softer than the encapsulation layer 103, and thus the dimension of the first sandblasting powders 60P is smaller than the dimension of the second sandblasting powders 62P. The first sandblasting powders 60P may also be softer than the second sandblasting powders 62P. To prevent the passivation layer 105 from being damaged, the first sandblasting operation 60 is performed prior to the second sandblasting operation 62. Since the encapsulation layer 103 is more rigid than the passivation layer 105, the encapsulation layer 103 can withstand the first sandblasting powders 60P during the first sandblasting operation 60 and is not damaged. By way of an example, the first sandblasting powders 60P may include resin powders having a dimension ranging from about 2 micrometers to about 4 micrometers, and the second sandblasting powders 62P may include glass powders having a dimension ranging from about 4 micrometers to about 8 micrometers or ceramic powders having a dimension ranging from about 10 micrometers to about 25 micrometers. By way of an example, the first sandblasting powders 60P may include glass powders having a dimension ranging from about 4 micrometers to about 8 micrometers, and the second sandblasting powders 62P may include ceramic powders having a dimension ranging from about 10 micrometers to about 25 micrometers.

After the second openings 103H are formed, a plurality of structures are singulated and picked up. The masking layer 56 and the masking layer 58 are then removed by e.g., etching to form a semiconductor device package 1 as shown in FIG. 1 or a semiconductor device package 2 as shown in FIG. 2. In some embodiments, the encapsulation layer 103 may be slightly cut or bombed during the first sandblasting operation 60, and have a profile of the second sidewall 103C as shown in FIG. 3.

In some other embodiments, the second openings 103H of the encapsulation layer 103 may be formed in another manner. For example, the second openings 103H of the encapsulation layer 103 may be formed by laser drilling. The second sidewall 103C formed by laser drilling may be inclining with respect to the fourth surface 103B, and the second sidewall 103C formed by laser drilling may be less rough than that formed by sandblasting as shown in FIG. 1 or FIG. 2. Alternatively, the second openings 103H of the encapsulation layer 103 may be formed by roller blade cutting. The second sidewall 103C formed by roller blade cutting may be substantially perpendicular to the fourth surface 103B as shown in FIG. 4. In some embodiments, the encapsulation layer 103 may be slightly cut or bombed during the first sandblasting operation 60, and have a profile of the second sidewall 103C as shown in FIG. 5.

In some embodiments of the present disclosure, the semiconductor device package includes an electronic component, an encapsulation layer and a passivation layer stacking with the encapsulation layer. The sidewall of the passivation layer may be formed by sandblasting and is inclining with respect to the surface of the passivation layer. Compared to roller blade cutting, sandblasting applies a unidirectional pulling force on the passivation layer, and thus can alleviate delamination and warpage issue due to mechanical stress. Sandblasting also generates less friction, and thus can reduce heat accumulation. Accordingly, delamination and warpage issue due to thermal stress can be alleviated.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

1. A semiconductor device package, comprising:
an electronic component;
an encapsulation layer encapsulating the electronic component; and
a passivation layer stacking with the encapsulation layer, wherein the passivation layer has a first surface facing the encapsulation layer, a second surface opposite to the first surface, and a first sidewall connecting the first surface and the second surface, the first sidewall inclining with respect to the second surface, wherein a first projection width of the encapsulation layer is greater than a second projection width of the passivation layer.

2. The semiconductor device package of claim 1, wherein the second surface is smaller than the first surface.

3. The semiconductor device package of claim 1, wherein the encapsulation layer has a third surface facing the passivation layer, a fourth surface opposite to the third surface, and a second sidewall connecting the third surface and the fourth surface.

4. The semiconductor device package of claim 3, wherein the encapsulation layer hangs over the passivation layer.

5. The semiconductor device package of claim 3, wherein a surface roughness of the second sidewall of the encapsulation layer is larger than a surface roughness of the first sidewall of the passivation layer.

6. The semiconductor device package of claim 3, wherein the third surface is larger than the fourth surface.

7. The semiconductor device package of claim 3, wherein the third surface of the encapsulation layer is larger than the first surface of the passivation layer.

8. The semiconductor device package of claim 3, wherein the second sidewall of the encapsulation layer is substantially perpendicular to the fourth surface.

9. The semiconductor device package of claim 1, further comprising a circuit layer between the passivation layer and the encapsulation layer, the circuit layer being electrically connected to the electronic component.

10. The semiconductor device package of claim 1, wherein the passivation layer is softer than the encapsulation layer.

11. A semiconductor device package, comprising:
a passivation layer having a first sidewall;
an electronic component disposed on the passivation layer;
an encapsulation layer stacked on the passivation layer and encapsulating the electronic component, the encapsulation layer having a second sidewall, wherein a surface roughness of the second sidewall of the encapsulation layer is different from a surface roughness of the first sidewall of the passivation layer.

12. The semiconductor device package of claim 11, wherein the surface roughness of the second sidewall of the encapsulation layer is larger than the surface roughness of the first sidewall of the passivation layer.

13. The semiconductor device package of claim 11, wherein the surface roughness of the second sidewall of the encapsulation layer is less than the surface roughness of the first sidewall of the passivation layer.

14. The semiconductor device package of claim 11, further comprising a filler cut and exposed from the second sidewall of the encapsulation layer.

15. The semiconductor device package of claim 11, wherein the passivation layer and the encapsulation layer are in contact at an interface.

16. The semiconductor device package of claim 15, wherein the first sidewall is inclining with respect to the interface, and the second sidewall is inclining with respect to the interface.

17. The semiconductor device package of claim 15, wherein the first sidewall is inclining with respect to the interface, and the second sidewall is substantially perpendicular to the interface.

18. A method for manufacturing a semiconductor device package, comprising:
forming a passivation layer on a carrier;
forming an electronic component on the passivation layer;
forming an encapsulation layer on the passivation layer to encapsulate the electronic component;
forming a first opening in the passivation layer by performing a first sandblasting operation; and
forming a second opening in the encapsulation layer, the second opening being in connection with the first opening.

19. The method of claim 18, wherein the forming the second opening in the encapsulation layer comprises performing a second sandblasting operation.

20. The method of claim 19, wherein a dimension of first sandblasting powders used in the first sandblasting operation is smaller than a dimension of second sandblasting powders used in the second sandblasting operation.

21. The semiconductor device package of claim 3, wherein an included angle between the second sidewall of the encapsulation layer and the third surface of the encapsulation layer is a fillet angle or a chamfer angle.

22. The semiconductor device package of claim 11, wherein the passivation layer is softer than the encapsulation layer.

23. The semiconductor device package of claim 15, wherein an included angle between the second sidewall of the encapsulation layer and the interface of the encapsulation layer is a fillet angle or a chamfer angle.
